(19) United States
(12) Patent Application Publication
(10) Pub. No.: US 2022/0285128 A1
(43) Pub. Date: Sep. 8, 2022

(54) SUBSTRATE PROCESSING APPARATUS, CEILING PLATE, AND RING MEMBER

(71) Applicant: Kioxia Corporation, Tokyo (JP)

(72) Inventor: Takashi OHASHI, Yokkaichi Mie (JP)

(73) Assignee: Kioxia Corporation, Tokyo (JP)

(21) Appl. No.: 17/468,178

(22) Filed: Sep. 7, 2021

(30) Foreign Application Priority Data
Mar. 4, 2021 (JP) 2021-034279

(51) Int. Cl. H01J 37/32

(52) U.S. Cl. CPC H01J 37/321; H01J 37/32715; H01J 37/3244; H01J 37/32642; H01J 2237/334

(57) ABSTRACT

A substrate processing apparatus according to an embodiment includes a support table, a power source, and a ceiling plate. The support table is provided inside a chamber to support a substrate to be processed. The power source supplies high frequency power toward the support table. The ceiling plate is provided inside the chamber to face the support table. The ceiling plate includes a first member whose inside is provided with an opening and a second member being fitted into the opening. A first crystal plane of a first material exposed on a first surface of the first member facing the support table is different from a second crystal plane of the first material exposed on a second surface of the second member facing the support table.

### CROSS-REFERENCE TO RELATED APPLICATIONS

This application is based upon and claims the benefit of priority from Japanese Patent Application No. 2021-034279, filed on Mar. 4, 2021; the entire contents of which are incorporated herein by reference.

### FIELD

Embodiments described herein relate generally to a substrate processing apparatus, a ceiling plate, and a ring member.

### BACKGROUND

In a substrate processing apparatus such as an etching apparatus using plasma, part of the inside of a chamber is exposed to a high concentration of plasma. Such a part can be found on, for example, the ceiling surface of the chamber. In order to reduce plasma-induced abrasion, a flat plate formed of a plasma-resistant material may be attached to the top of the chamber. However, the abrasion on the flat plate, in particular at the central portion where the plasma density becomes higher, cannot be avoided. Therefore, there is a need to reduce frequency of replacing the flat plate due to the abrasion.

### BRIEF DESCRIPTION OF THE DRAWINGS

FIG. 1 is a cross-sectional view schematically illustrating a substrate processing apparatus according to an embodiment;

FIG. 2A is a top view illustrating a ceiling plate of the substrate processing apparatus according to the embodiment;

FIG. 2B is a cross-sectional view of the ceiling plate taken along line L-L of FIG. 2A; and

FIG. 3 is a top view schematically illustrating a support table of the substrate processing apparatus according to the embodiment.

### DETAILED DESCRIPTION

A substrate processing apparatus according to an embodiment includes a support table, a power source, and a ceiling plate. The support table is provided inside a chamber to support a substrate to be processed. The power source supplies high frequency power toward the support table. The ceiling plate is provided inside the chamber to face the support table. The ceiling plate includes a first member whose inside is provided with an opening and a second member being fitted into the opening. A first crystal plane of a first material exposed on a first surface of the first member facing the support table is different from a second crystal plane of the first material exposed on a second surface of the second member facing the support table.

Non-limiting exemplary embodiments of the invention will be described below with reference to the accompanying drawings. In the accompanying drawings, the same or corresponding members or parts are denoted by the same or corresponding reference signs, and overlapping descriptions are omitted. The drawings are not intended to illustrate relative ratios between members or parts, or between the thicknesses of the various layers, and thus specific thicknesses and dimensions are to be determined by those skilled in the art in light of the following non-limiting embodiments.

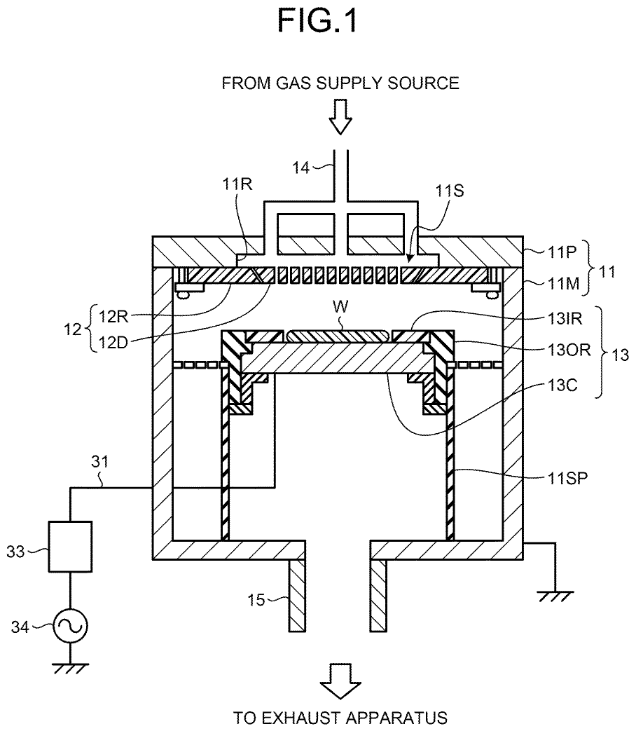

The substrate processing apparatus according to the present embodiment will be described with reference to FIG. 1. FIG. 1 is a cross-sectional view schematically illustrating the substrate processing apparatus according to the present embodiment. A substrate processing apparatus 1 according to the present embodiment is a capacitively coupled plasma etching apparatus, and as illustrated, the substrate processing apparatus 1 includes a chamber 11, a support table 13, and a ceiling plate 12.

The chamber 11 includes a top plate 11P and a chamber body 11M, each being formed of, for example, aluminum. The top plate 11P and the chamber body 11M are hermetically coupled to each other by, for example, an O-ring. The top plate 11P is provided with a recess part 11R opening toward the inside of the chamber 11. The recess part 11R is provided with a plurality of openings on its bottom face (that is, a ceiling face viewed from the inside of the chamber 11). A gas supply pipe 14 is connected to the openings. A predetermined type of gas is supplied from a gas supply source to the gas supply pipe 14. The chamber body 11M includes a gas exhaust port provided on a lower portion of the chamber body 11M, to which an exhaust pipe 15 is connected. The exhaust pipe 15 is connected to a vacuum pump (not illustrated), and thereby the inside of the chamber 11 can be maintained at a reduced pressure. Although not illustrated, the side face of the chamber body 11M is provided with a transfer port for carrying in and out a wafer W into and from the chamber 11, and the transfer port is provided with a gate valve.

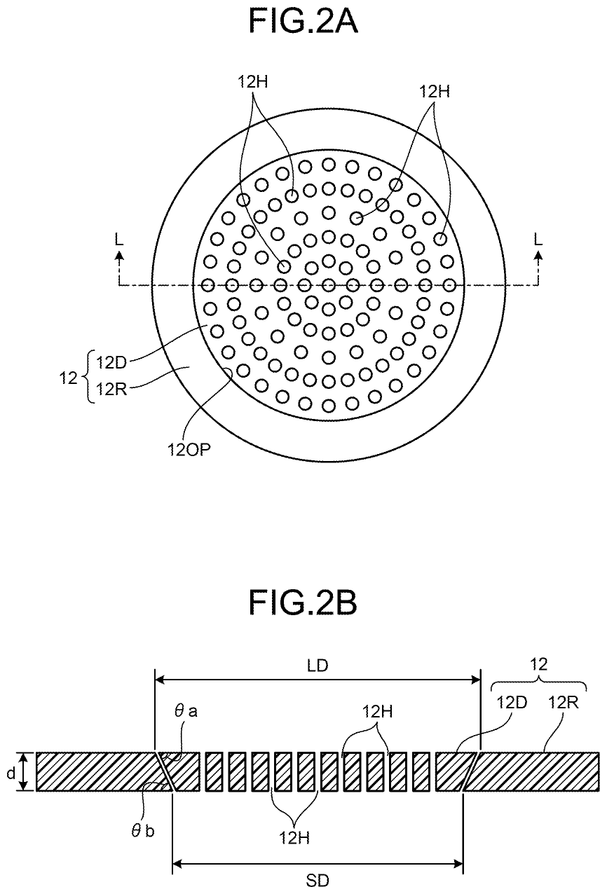

The ceiling plate 12 will then be described with reference to FIGS. 2A and 2B in addition to FIG. 1. FIG. 2A is a top view (a view viewed from the top plate 11P side) illustrating the ceiling plate 12. FIG. 2B is a cross-sectional view taken along line L-L of FIG. 2A. As illustrated in FIG. 1, the ceiling plate 12 is disposed above the support table 13 in the chamber 11 to face the support table 13. As illustrated in FIG. 2A, the ceiling plate 12 includes a first member 12R having a ring shape and a second member 12D inside the first member. An outer peripheral face of the second member 12D is inclined, so that this member 12D has a flat truncated cone shape. On the other hand, the first member 12R has an opening 120P inside. The opening 120P has a larger inner diameter LD on the upper face (the face facing the top plate 11P) of the first member 12R, and has an inner diameter SD on the lower face (the face facing the support table 13), which is smaller than the inner diameter LD. The inner diameter SD and the inner diameter LD are located concentrically with each other, and thus the inner peripheral face of the opening 120P of the first member 12R is inclined in a truncated cone shape.

As illustrated in FIG. 2B, the inclination angle 8b of the inner peripheral face of the first member 12R and the inclination angle 8a of the outer peripheral face of the second member 12D are substantially equal to each other (although the angles may include errors in manufacturing, for example). The second member 12D has a thickness substantially equal to the thickness d of the first member 12R. In addition, the outer diameter of the lower face of the second member 12D and the inner diameter SD of the lower face of the first member 12R are equal to each other. Therefore, the second member 12D is closely fitted into the opening 120P of the first member 12R. As a result, the upper faces of these two members 12D and 12R are flush with each other, and their lower faces are also flush with each other.

As illustrated in FIG. 1, the edge of the first member 12R is fixed to the lower face of the top plate 11P by a predetermined jig in a state where the second member 12D is fitted into the first member 12R. Thus, the ceiling plate 12 is attached in the chamber 11 such that its upper face faces the top plate 11P and its lower faces the support table 13. The second member 12D is fitted into the first member 12R, so that it is held by the first member 12R without falling. Therefore, there is no need to attach the second member 12D to the first member 12R by using, for example, a jig or an adhesive, and thereby undesired contamination can be prevented.

As illustrated in FIG. 2A, the second member 12D is provided with a plurality of discharge holes 12H. The discharge holes 12H may be arranged, for example, along a plurality of concentric circles. In the state where the ceiling plate 12 is attached to the top plate 11P as illustrated in FIG. 1, the recess part 11R of the top plate 11P is closed by the second member 12D, and a space 11S is formed by the recess part 11R. As described above, the space 11S is in communication with the gas supply pipe 14, so that gas is supplied from the gas supply source to the space 11S. The ceiling plate 12 has a plurality of discharge holes 12H, and can function as a so-called shower head. Specifically, the gas supplied to the space 11S spreads substantially uniformly in the space 11S, and can be supplied uniformly through the plurality of discharge holes 12H of the ceiling plate 12 toward the wafer W disposed on the support table 13. Since the second member 12D is closely fitted inside the first member 12R, the flow of gas between these members 12D and 12R is also prevented. Additionally, as described above, the upper faces of the second member 12D and the first member 12R are flush with each other, so that the flow and uniformity of gas in the space 11S can be prevented from being reduced. The lower faces of the second member 12D and the first member 12R are also flush with each other, so that the spacing between the ceiling plate 12 and the wafer W disposed on the support table 13 can be uniform.

When the substrate processing apparatus 1 according to the present embodiment is used, for example, for etching a metal, a silicon nitride film, or a silicon oxide film, the ceiling plate 12 may be formed of silicon. Note that in this case, a (111) crystal plane (hereinafter referred to simply as “plane”) of silicon is exposed on the lower face (the face facing the support table 13 in the chamber 11) of the second member 12D, and a (001) plane of silicon, which is different from the (111) plane, is exposed on the lower face of the first member 12R. The second member 12D and the first member 12R can be formed, for example, from an ingot pulled by means of a Czochralski method. Specifically, the first member 12R can be formed from a plate-like body (or silicon wafer) obtained by slicing an ingot on the (001) plane, and the second member 12D can be formed from a plate-like body obtained by slicing an ingot on the (111) plane. In the following description, in order to include equivalent planes, the (001) plane is collectively referred to as a <100> plane, and the (111) plane is collectively referred to as a <111> plane.

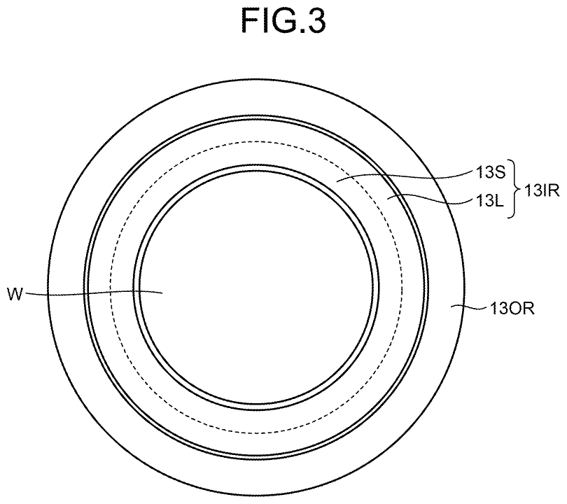

The support table 13 will then be described with reference to FIG. 3 in addition to FIG. 1. FIG. 3 is a top view schematically illustrating the support table 13. As illustrated in

FIG. 1, the support table 13 is held at approximately the center of the interior of the chamber 11 as viewed from above, for example, by a plurality of struts 11SR The support table 13 includes a susceptor 13C, an outer peripheral ring member 130R, and an inner peripheral ring member 13IR. The susceptor 13C is formed of, for example, aluminum. The susceptor C has an outer diameter larger than that of the wafer W, and supports the wafer W with its upper face. On the susceptor 13C, a holding mechanism (not illustrated), such as an electrostatic chuck for electrostatically holding the wafer W, may be provided. The surface of the susceptor 13C may be coated with, for example, aluminum oxide (Al₂O₃) or yttrium oxide (Y₂O₃). Moreover, a heating mechanism for maintaining the wafer W at a predetermined temperature may be provided inside the susceptor 13C.

The susceptor 13C also serves as a lower electrode. Specifically, the susceptor 13C is connected to a feeder line 31 for supplying high frequency power, and the feeder line 31 is connected to a high frequency power source 34 via a matching unit 33. The high frequency power source 34 supplies high frequency power of a predetermined frequency toward the susceptor 13C. On the other hand, the ceiling plate 12, which faces the support table 13 and is grounded via the chamber 11, functions as an upper electrode. In other words, the high frequency power supplied to the susceptor 13C generates an electric field in the chamber 11 between the susceptor 13C (the support table 13) and the ceiling plate 12, thereby generating plasma.

The outer peripheral ring member 13OR is provided along the side face of the susceptor 13C. The inner peripheral ring member 13IR is positioned inside the outer peripheral ring member 130R and is placed on the upper face of the susceptor 13C. The outer peripheral ring member 130R and the inner peripheral ring member 13IR are provided for adjusting an electric field so as not to deflect the electric field at the peripheral edge of the wafer W during etching of the wafer W.

The inner peripheral ring member 131R (an example of a ring member) has a flat ring shape as a whole and includes a small diameter portion 13S (an example of an inner ring portion) and a large diameter portion 13L (an example of an outer ring portion). The small diameter portion 13S and the large diameter portion 13L may be formed of silicon, for example. The small diameter portion 13S is fitted inside the large diameter portion 13L. The inner diameter of the large diameter portion 13L is slightly larger than the outer diameter of the small diameter portion 13S so that the small diameter portion 13S can be closely housed inside the large diameter portion 13L. The inner diameter of the small diameter portion 13S is larger than the outer diameter of the wafer W. Thus, the inside of the inner peripheral ring member 13IR on the susceptor 13C is the area where the wafer W is placed.

In the present embodiment, the <111> plane of the silicon crystal is exposed on the upper face (the face facing the ceiling plate 12) of the small diameter portion 13S, and the <100> plane is exposed on the upper face of the large diameter portion 13L. 100221 The outer peripheral ring member 130R may be formed of, for example, a ceramic material or an insulating material such as resin. The outer peripheral ring member 130R is desirably formed of an insulating material having high plasma resistance such as Al₂O₃ or Y₂O₃. Moreover, the outer peripheral ring member 130R may be provided so as to be vertically movable by a driving mechanism (not illustrated) in order to adjust the electric field distribution. Thus, even if the upper face of the outer peripheral ring member 130R is worn out and the distance between the upper face and the ceiling plate 12 is increased, the distance can be adjusted by raising the outer peripheral ring member 130R, thereby preventing the electric field distribution (and thus the plasma distribution) from being changed.

Advantages brought by the substrate processing apparatus 1 configured as described above will be described below. As described above, the ceiling plate 12 includes the second member 12D and the first member 12R. The <111> plane is exposed on the lower face of the second member 12D, and the <100> plane is exposed on the lower face of the first member 12R. When a processing gas containing a predetermined etching gas, an auxiliary gas, and a dilution gas is supplied to the chamber 11 of the substrate processing apparatus 1, the inside of the chamber 11 is maintained at a predetermined pressure, and high frequency power is supplied to the susceptor 13C as a lower electrode, plasma is generated inside the chamber 11 of the substrate processing apparatus 1. The generated plasma can be distributed with substantially equal density in a predetermined range including the center of the support table 13, whereas the plasma density gradually decreases outside the range. In other words, while the first member 12R is exposed to plasma having relatively low density, the second member 12D is exposed to plasma having high density. Therefore, the second member 12D is worn out more than the first member 12R by plasma.

If assuming that the <100> plane is exposed on the lower face of the second member 12D as well as that of the first member 12R, the second member 12D may be worn out more than the first member 12R by plasma, and thereby the central portion of the ceiling plate 12 may be scooped out. The spacing between the ceiling plate 12 and the support table 13 (or the wafer W on the support table 13) increases near the center of the ceiling plate 12 and decreases toward the periphery of the ceiling plate 12. Therefore, the distribution of the plasma generated between the ceiling plate 12 and the support table 13 may change and the in-plane uniformity of the wafer W in the processing (etching) for the wafer W may deteriorate. In order to prevent this deterioration (even if the first member 12R is not so worn out), the ceiling plate 12 must be regularly replaced.

By contrast, the ceiling plate 12 according to the present embodiment is configured such that the <111> plane is exposed on the lower face of the inner second member 12D, the <100> plane is exposed on the lower face of the first member 12R, and the <111> plane has plasma resistance higher than that of the <100> plane. Therefore, the central portion of the ceiling plate 12 is hard to be scooped out. As a result, the replacement frequency of the ceiling plate 12 can be reduced, and thus the labor and cost required for the maintenance of the substrate processing apparatus 1 can be reduced.

Moreover, in the second member 12D exposed to high-density plasma, the <111>plane having etching resistance higher than the <100> plane is exposed on the lower face of the second member 12D. In the first member 12R exposed to relatively low-density plasma, the <100> plane is exposed on the lower face of the first member 12R. Thus, the lower faces of the two members 12D and 12R can be uniformly worn out. Therefore, the deterioration of the uniformity of the process due to the uneven spacing between the ceiling plate 12 and the support table 13 (that is, due to the fact that the spacing increases in the central portion and decreases in the peripheral portion) can be reduced.

Also in the inner peripheral ring member 13IR, the <111> plane is exposed to the inner small diameter portion 13S, and the <100> plane is exposed to the outer large diameter portion 13L. The plasma density tends to increase from the outer peripheral portion to the inner peripheral portion of the inner peripheral ring member 131R, so that the inner peripheral portion tends to be worn out more easily than the outer peripheral portion. However, since the <111> plane is exposed to the small diameter portion 13S, such a tendency can be offset.

Moreover, in the same manner as described for the second member 12D and the first member 12R of the ceiling plate 12, the small diameter portion 13S and the large diameter portion 13L of the inner peripheral ring member 13IR can be uniformly worn out regardless of the plasma density distribution (difference). If assuming that the <100> plane is also exposed to the small diameter portion 13S, the small diameter portion 13S is worn out early, and the distance between the small diameter portion 13S and the ceiling plate 12 becomes larger than the distance between the large diameter portion 13L and the ceiling plate. Thus, the plasma distribution on the support table 13 is changed. However, when the inner peripheral ring member 13IR is uniformly worn out, the change in plasma distribution caused by the difference in abrasion between the inner peripheral portion and the outer peripheral portion of the inner peripheral ring member 13IR can be prevented.

If the <100> plane is exposed to both the small diameter portion 13S and the large diameter portion 13L, the small diameter portion 13S may be devised to be raised or lowered so that the small diameter portion 13S is raised by the amount that the small diameter portion 13S is thinned by abrasion, in consideration of the fact that the inner peripheral portion of the inner peripheral ring member 13IR is easily worn out by plasma.

However, in this case, a driving mechanism is required to be provided only for the small diameter portion I3S, which results in a complicated etching apparatus and requires costs and labor for its maintenance. On the other hand, in the inner peripheral ring member 13IR of the present embodiment, the <111> plane having etching resistance higher than the <100> plane is exposed on the upper face of the small diameter portion 13S, so that abrasion in the small diameter portion 13S exposed to high-density plasma can be reduced. Therefore, the frequency of maintenance can be reduced, and the substrate processing apparatus 1 is not unnecessarily complicated.

Note that a silicon ring may be placed on the upper face of the outer peripheral ring member 130R substantially concentrically with the inner peripheral ring member 131R. When the upper face of the outer peripheral ring member 130R is worn out by plasma, the entire outer peripheral ring member 130R must be replaced, while when such a ring is placed on the upper face of the outer peripheral ring member 130R, even if the ring is worn out, only the ring needs to be replaced. In other words, the labor required for the maintenance work can be reduced.

Examples of Modification

While the ceiling plate 12 described above is formed of silicon, it may be formed of aluminum oxide (Al₂O₃), yttrium oxide (Y₂O₃), or silicon carbide (SiC). Even when the ceiling plate 12 is formed of such a material, the second member 12D and the first member 12R can have the same configuration as that described above. Specifically, different crystal planes are exposed on the lower face of the second member 12D and the lower face of the first member 12R. The crystal plane exposed on the lower face of the second member 12D has plasma resistance higher than that of the crystal plane exposed on the lower face of the first member 12R. Note that, in general, the etching resistance tends to be high when the number of bonding hands appearing on the crystal plane is small and low when the number of bonding hands is large. Therefore, a specific crystal plane may be determined in consideration of such tendency and ease of preparation.

The inner peripheral ring member 13IR is also not limited to silicon, and may be formed of aluminum oxide (Al₂O₃), yttrium oxide (Y₂O₃), or silicon carbide (SiC). Also in this case, the crystal plane exposed on the upper face of the small diameter portion 13S has plasma resistance higher than that of the crystal plane exposed on the upper face of the large diameter portion 13L.

Note that the second member 12D and the first member 12R of the ceiling plate 12 in the substrate processing apparatus 1 may be formed of silicon, yttrium oxide, fluorite-type crystal structure, or silicon carbide, as described above. Accordingly, the ceiling plate 12 as a whole is formed of a single (or the same) material. If the second member 12D and the first member 12R are formed of materials different from each other, the conductivities of both the members are different from each other, so that the uniformity of the plasma distribution may be affected. In this case, adjustments may be necessary to compensate for the difference in conductivity. On the other hand, the present embodiment can eliminate the need of such adjustments because the ceiling plate 12 as a whole is formed of a single (or the same) material and thereby the conductivity is constant.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate processing apparatus comprising:
a support table provided inside a chamber to support a substrate to be processed;
a power source configured to supply high frequency power toward the support table; and
a ceiling plate provided inside the chamber to face the support table, the ceiling plate including
a first member whose inside is provided with an opening, and
a second member being fitted into the opening,
wherein a first crystal plane of a first material exposed on a first surface of the first member facing the support table is different from a second crystal plane of the first material exposed on a second surface of the second member facing the support table.

2. The substrate processing apparatus according to claim 1, wherein the second crystal plane has plasma resistance higher than that of the first crystal plane.

3. The substrate processing apparatus according to claim 1, wherein
the first material is silicon,
the first crystal plane is a <100> plane, and
the second crystal plane is a <111> plane.

4. The substrate processing apparatus according to claim 1, wherein the first material is aluminum oxide, yttrium oxide, or silicon carbide.

5. The substrate processing apparatus according to claim 1, wherein
an inner side face of the opening of the first member is inclined,
an outer side face of the second member is inclined, and
the second member is provided in the opening of the first member in a state where the outer side face of the second member is in contact with the inner side face of the opening of the first member.

6. The substrate processing apparatus according to claim 1, wherein
the support table includes a ring member surrounding a region where the substrate is supported,
the ring member includes an outer ring portion and an inner ring portion provided inside the outer ring portion, and
a first crystal plane of a second material exposed on a third surface of the inner ring portion facing the ceiling plate is different from a second crystal plane of the second material exposed on a fourth surface of the outer ring portion facing the ceiling plate.

7. The substrate processing apparatus according to claim 6, wherein the second crystal plane has plasma resistance higher than that of the first crystal plane.

8. The substrate processing apparatus according to claim 6, wherein
the second material is silicon,
the first crystal plane is a <100> plane, and
the second crystal plane is a <111> plane.

9. The substrate processing apparatus according to claim 6, wherein the second material is aluminum oxide, yttrium oxide, or silicon carbide.

10. The substrate processing apparatus according to claim 1, wherein
the chamber includes a gas supply port through which gas is supplied, the gas supply port being provided at an opposite side of the support table across the ceiling plate, and
the second member of the ceiling plate includes a plurality of discharge ports allowing the gas to pass toward the support table.

11. A ceiling plate comprising:
a first member whose inside is provided with an opening; and
a second member fitted into the opening,
wherein a first crystal plane of a material exposed on a surface of the first member is different from a second crystal plane of the material exposed on a surface of the second member.

12. The ceiling plate according to claim 11, wherein the second crystal plane has plasma resistance higher than that of the first crystal plane.

13. The ceiling plate according to claim 11, wherein
the first material is silicon,
the first crystal plane is a <100> plane, and
the second crystal plane is a <111> plane.

14. The ceiling plate according to claim 11, wherein the first material is aluminum oxide, yttrium oxide, or silicon carbide.

15. The ceiling plate according to claim 11, wherein
an inner side face of the opening of the first member is inclined,
an outer side face of the second member is inclined, and
the second member is provided in the opening of the first member in a state where the outer side face of the second member is in contact with the inner side face of the opening of the first member.

16. A ring member including:
an outer ring portion; and
an inner ring portion provided inside the outer ring portion,
wherein a first crystal plane of a material exposed on a surface of the inner ring portion is different from a second crystal plane of the material exposed on a surface of the outer ring portion.

17. The ring member according to claim 16, wherein the second crystal plane has plasma resistance higher than that of the first crystal plane.

18. The ring member according to claim 16, wherein
the second material is silicon,
the first crystal plane is a <100> plane, and
the second crystal plane is a <111> plane.

19. The ring member according to claim 16, wherein the second material is aluminum oxide, yttrium oxide, or silicon carbide.
